(19) United States
(12) Patent Application Publication
(10) Pub. No.: US 2015/0000958 A1
(43) Pub. Date: Jan. 1, 2015

(54) PRINTED CIRCUIT BOARD AND METHOD OF FABRICATING THE SAME

(71) Applicant: Samsung Electro-Mechanics Co., Ltd., Suwon (KR)

(72) Inventors: Kyoung Moo HARR, Suwon (KR); Hyung Jin JEON, Suwon (KR); Jin Gu KIM, Suwon (KR); Young Jae LEE, Suwon (KR); Young Do KWEON, Suwon (KR); Chang Bae LEE, Yongin (KR)

(73) Assignee: SAMSUNG ELECTRO-MECHANICS CO., LTD., Suwon (KR)

(21) Appl. No.: 14/074,338

(22) Filed: Nov. 7, 2013

(30) Foreign Application Priority Data
Jul. 1, 2013 (KR) 10-2013-0076447

(51) Int. Cl. H05K 1/02; H05K 3/46; H05K 3/00

(52) U.S. Cl. CPC H05K 1/0298; H05K 3/0082; H05K 3/4644
USPC 174/251; 205/125

(57) ABSTRACT

The present invention discloses a printed circuit board including a lower wiring layer, an insulating layer which buries the lower wiring layer, and an upper wiring layer formed on the insulating layer to improve reliability of interlayer electrical connection between the wiring layers, wherein the interlayer connection between the upper wiring layer and the lower wiring layer is performed by a via electrode which is provided between the upper wiring layer and the lower wiring layer and has an upper surface bonded to the upper wiring layer and a lower surface bonded to the lower wiring layer, wherein the lower surface of the via electrode is larger than the upper surface thereof.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2013-0076447, entitled filed Jul. 1, 2013, which is hereby incorporated by reference in its entirety into this application.

### BACKGROUND OF THE INVENTION

1. Field of the Invention

The present invention relates to a printed circuit board, and more particularly, to a printed circuit board having a via electrode structure of specific shape for interlayer connection of wiring layers.

2. Description of the Related Art

A printed circuit board (PCB) is formed by printing a circuit line pattern on an electrical insulating substrate using a conductive material such as copper. With the trend of miniaturization, thinning, high density, and packaging of electronic products, the multilayer board and the improvement of wiring density of the printed circuit board also have been studied and developed.

In order to improve the fine pattern formation, reliability, and design density of the printed circuit board, the layer configuration of a circuit becomes complex with changes in raw materials. Accordingly, in addition to a single-sided PCB in which wiring is formed only on one surface of an insulating substrate, a double-sided PCB in which wirings are formed on both surfaces and a multilayer board in which wirings are formed in plurality of layers are widely used.

Among them, the multilayer board is manufactured by a build-up method to expand the mounting area of a circuit wiring layer. In the multilayer board by a build-up method, an insulating layer and the circuit wiring layer are sequentially stacked, and the circuit wiring layers of respective layers are conducted using a via electrode.

Looking into a typical method of forming a via electrode with reference to Korean Patent Laid-Open Publication No. 2013-0051286, first, a circuit wiring layer of a first layer is formed on a substrate member, an insulating layer is coated to cover the circuit wiring layer of the first layer, and a via hole is processed in the predetermined position of the insulating layer by a laser process or a photolithography process to expose the circuit wiring layer of the first layer. Next, a circuit wiring layer of a second layer is formed on the insulating layer. At this time, the inside of the via hole is plated by a via fill process to connect the circuit wiring layer of the first layer and the circuit wiring layer of the second layer.

Meanwhile, initially, the interlayer connection is performed by crossing via electrodes of respective layers each other, but in recent times, since high speed signal characteristics are required according to high function, miniaturization, and high density of electronic devices, a stack via structure in which a via electrode of a second layer is stacked directly on a via electrode of a first layer has been proposed. This stack via structure can reduce circuit design time up to 30% or more compared to existing products and is excellent in electrical characteristics such as signal loss or signal interference. Therefore, in the stack via structure, since the via electrode is formed directly on the via electrode, the inside of the via hole should be completely filled with a metal.

### RELATED ART DOCUMENT

### Patent Document

Patent Document 1: Korean Patent Laid-Open Publication No. 2013-0051286

### SUMMARY OF THE INVENTION

However, according to the increasing aspect ratio of a via hole, a void phenomenon that a metal material is not filled in some areas inside the via hole may occur when filling the metal by a via fill process.

Further, the direction of filling the metal starts from the sidewall of the via hole and proceeds toward the center side of the via hole. Due to this, a dimple phenomenon that a groove is formed in the surface of a via electrode may occur due to a reduction in the amount of the metal filled in the center of the via hole.

This void or dimple phenomenon deteriorates reliability of interlayer electrical connection of circuit wiring layers, thus causing mass production of defective printed circuit boards. It is, therefore, an object of the present invention to provide a printed circuit board having structural stability and high reliability of electrical connection, and a method of fabricating the same.

In accordance with one aspect of the present invention to achieve the object, there is provided a printed circuit board including a lower wiring layer, an insulating layer which buries the lower wiring layer, and an upper wiring layer formed on the insulating layer, wherein the interlayer connection between the upper wiring layer and the lower wiring layer is performed by a via electrode which is provided between the upper wiring layer and the lower wiring layer and has an upper surface bonded to the upper wiring layer and a lower surface bonded to the lower wiring layer, wherein the lower surface of the via electrode is larger than the upper surface thereof.

Further, the via electrode has a tapered sidewall so that the diameter thereof increases downward.

Further, the insulating layer is formed to bury the lower wiring layer and the via electrode after the via electrode is formed.

Further, the wiring layer consists of one or a combination of a signal line, a power line, and a ground line.

In accordance with another aspect of the present invention to achieve the object, there is provided a printed circuit board formed by repeatedly stacking a wiring layer and an insulating layer which buries the wiring layer on one or both surfaces of a substrate member, wherein the interlayer connection between the wiring layers is performed by a via electrode which is provided between the wiring layers and has a lower surface bonded to the wiring layer buried in the insulating layer and an upper surface bonded to the wiring layer formed on the insulating layer based on one insulating layer, wherein the lower surface of the via electrode is larger than the upper surface thereof.

Further, the via electrode has a tapered sidewall so that the diameter thereof increases downward.

Further, the via electrodes of the respective layers are disposed to face each other in the vertical direction.

And in accordance with another aspect of the present invention to achieve the object, there is provided a method of fabricating a printed circuit board, including: forming a lower wiring layer on a substrate member; applying a photoresist on the surface of the substrate member on which the lower wiring layer is formed; exposing the lower wiring layer by forming a tapered via hole, whose diameter increases downward, in the photoresist; forming a via electrode by filling the inside of the via hole through plating; removing the photoresist; forming an insulating layer to bury the lower wiring layer and the via electrode; and forming an upper wiring layer on the insulating layer to be bonded to an upper surface of the via electrode.

Further, in forming the insulating layer, the insulating layer is formed to have a thickness corresponding to the sum of the thickness of the lower wiring layer and the thickness of the via electrode.

Further, the lower wiring layer and the upper wiring layer are formed by one of a subtractive method, an additive method, a semi-additive method, and a modified semi-additive (MSAP) method.

Further, the photoresist is a negative type that is cured by light irradiation, and in forming the via hole, the via hole is formed by performing exposure and development after attaching an exposure mask to the photoresist in the position in which the via electrode is to be formed.

Further, the area of the exposure mask attached to the position in which the via electrode is to be formed corresponds to the area of the upper surface of the via electrode.

Further, in forming the via electrode, the via electrode is formed by performing electroplating using the lower wiring layer as a lead wire.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a multilayer printed circuit board in accordance with the present invention;

FIG. 2 is a cross-sectional view of a printed circuit board in accordance with another embodiment of the present invention; and

FIGS. 3 to 10 are views sequentially showing a method of fabricating a printed circuit board of the present invention.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Hereinafter, configuration and operational effects of the present invention will be described in detail with reference to the accompanying drawings.

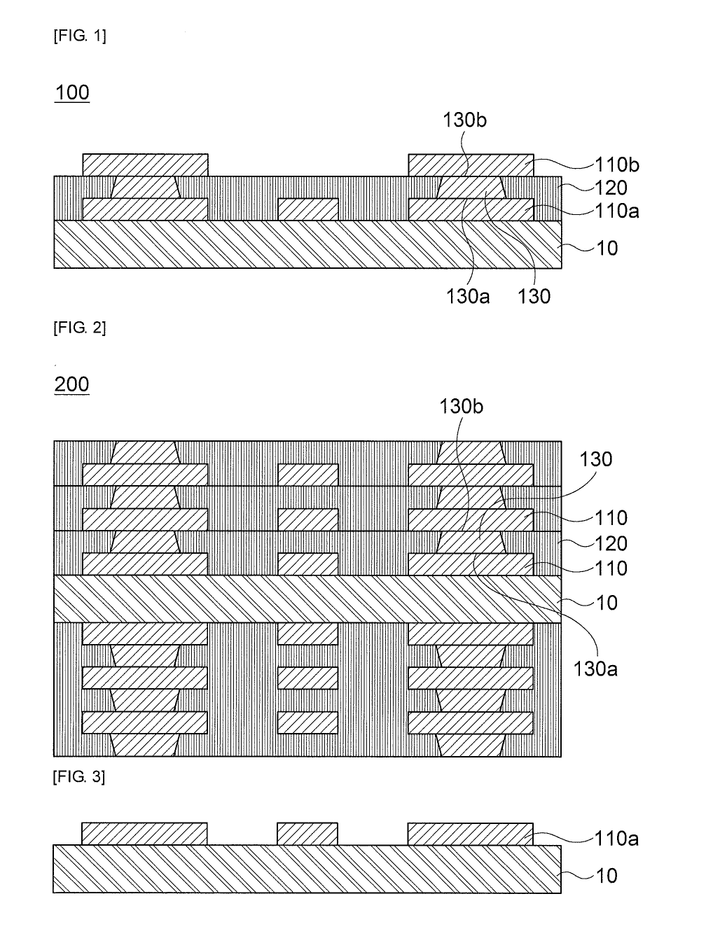

FIG. 1 is a cross-sectional view of a multilayer printed circuit board in accordance with the present invention. Additionally, elements in the drawing are not necessarily drawn to scale. For example, the dimensions of some of the elements in the figures may be exaggerated relative to other elements to help improve understanding of embodiments of the present invention.

Referring to FIG. 1, a printed circuit board 100 of the present invention may include a lower wiring layer 110a, an insulating layer 120 which buries the lower wiring layer 110a, and an upper wiring layer 110b formed on the insulating layer 120.

In order to clearly describe only the main features of the invention, although the drawing shows that the upper and lower wiring layers 110a and 110b and the insulating layer 120 are formed only on one surface of a substrate member 10 as a core, the upper and lower wiring layers 110a and 110b and the insulating layer 120 can be formed on both surfaces of the substrate member 10 as well as on the one surface of the substrate member 10.

The upper and lower wiring layers 110a and 110b are circuit wirings through which current flows and may be made of at least one material or a mixture of at least two materials selected from silver (Ag), palladium (Pd), aluminum (Al), nickel (Ni), titanium (Ti), gold (Au), copper (Cu), and platinum (Pt) which have high electrical conductivity. And the upper and lower wiring layers 110a and 110b may consist of one or a combination of a signal line which plays a role of an electrical path to transmit a signal, a power line which is a means of power supply, and a ground line which forms a ground area according to the purpose thereof.

Here, the interlayer connection between the upper wiring layer 110b and the lower wiring layer 110a may be performed by a via electrode 130 provided between the upper wiring layer 110b and the lower wiring layer 110a. That is, an upper surface 130b of the via electrode 130 is bonded to the upper wiring layer 110b and a lower surface 130a of the via electrode 130 is bonded to the lower wiring layer 110a.

At this time, the lower surface 130a of the via electrode 130 may be larger than the upper surface 130b. Accordingly, the via electrode 130, as shown in FIG. 1, may have a tapered sidewall, that is, a trapezoid shape so that the diameter thereof increases downward. The effect of including this type of the via electrode 130 will be described later.

The insulating layer 120 is a layer for protecting the upper and lower wiring layers 110a and 110b and insulating between the upper wiring layer 110b and the lower wiring layer 110a and the material thereof may be appropriately selected in consideration of insulation properties, heat resistance, and moisture resistance. For example, the optimum polymer material for forming the insulating layer 120 may be a thermosetting resin such as an epoxy resin, a thermoplastic resin such as polyimide, or a resin impregnated with a reinforcing agent such as glass fiber or inorganic filler, for example, prepreg.

This insulating layer 120 may be formed to bury the lower wiring layer 110a and the via electrode 130 after the via electrode 130 is formed. At this time, the thickness of the insulating layer 120 may have a value corresponding to the sum of the thickness of the lower wiring layer 110a and the thickness of the via electrode 130 so that the upper surface 130b of the via electrode 130 is bonded to the upper wiring layer 110b.

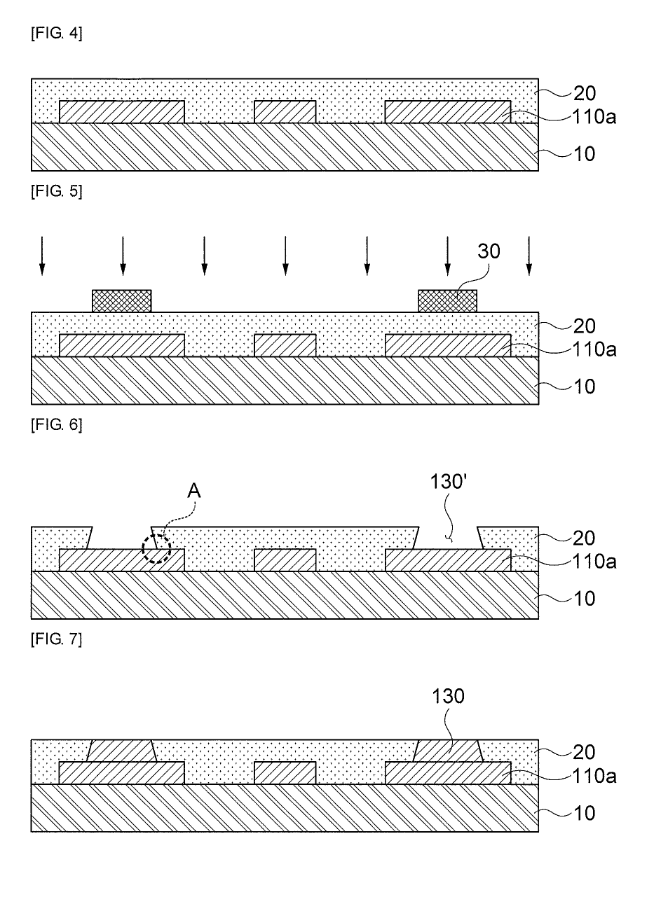

FIG. 2 is a cross-sectional view of a printed circuit board in accordance with another embodiment of the present invention. A printed circuit board 200 in accordance with another embodiment of the present invention includes three or more layers of wiring layers 110 and thus the above-described trapezoid via electrode 130 may consist of a plurality of layers of at least two or more layers.

That is, the printed circuit board 200 in accordance with another embodiment of the present invention is formed by repeatedly laminating the wiring layer 110 and an insulating layer 120 which buries the wiring layer 110. Although the drawing shows that the wiring layer 110 and the insulating layer 120 are formed on both surfaces of a substrate member 10, the wiring layer 110 and the insulating layer 120 can be formed only on one surface of the substrate member 10 in a plurality of layers.

Here, the interlayer connection between the wiring layers 110 is performed by the via electrode 130 which is provided between the wiring layers 110. That is, a lower surface 130a of the via electrode 130 is bonded to the wiring layer 110 buried in the insulating layer 120 and an upper surface 130b thereof is bonded to the wiring layer 110 formed on the insulating layer based on one insulating layer 120. And, as described above, the via electrode 130 may have a trapezoid shape in which the area of the lower surface 130a is larger than the upper surface 130b.

The via electrodes 130 of the respective layers may be disposed in the positions opposite to each other in the vertical direction. Therefore, the printed circuit board 200 in accordance with another embodiment of the present invention may have a stack via structure in which another via structure 130 is continuously stacked directly on one via structure 130.

In this stack via structure, defects such as warpage of a substrate may occur due to accumulation of stacking load caused by continuous stacking of the via electrodes, but when using the trapezoid via electrode 130 as in the present invention, it is possible to maintain a structurally stable form by dispersing the stacking load concentrated on the via electrode 130 of each layer to the larger lower portion.

Now, a method of fabricating a printed circuit board of the present invention will be described.

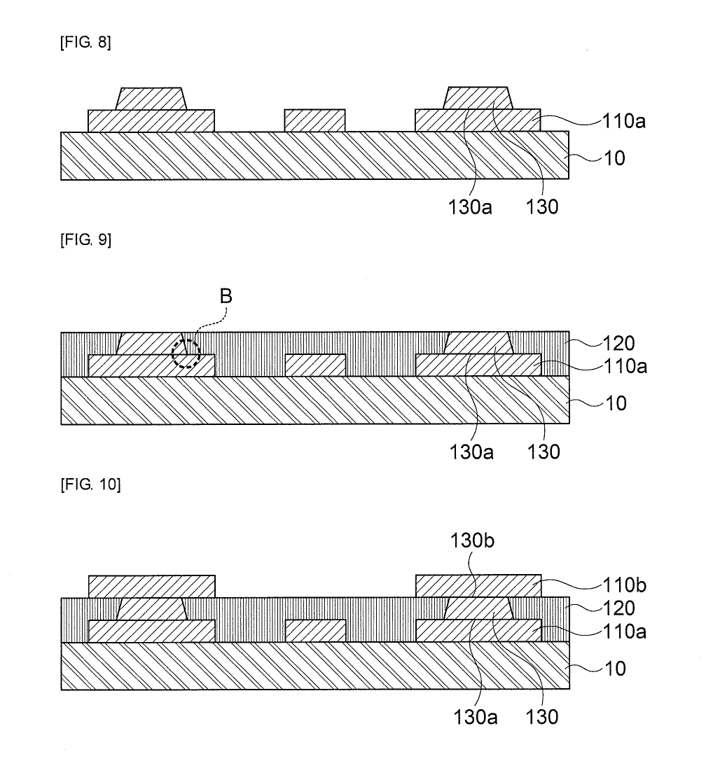

FIGS. 3 to 10 are views sequentially showing a method of fabricating a printed circuit board of the present invention. First, as in FIG. 3, the step of forming a lower wiring layer 110a on a substrate member 10 is performed.

The substrate member 10 is a core substrate and may be a thermosetting or thermoplastic polymer substrate, a ceramic substrate, an organic-inorganic composite material substrate, or a glass fiber-impregnated substrate.

And the lower wiring layer 110a may be formed by one of the generally known circuit forming methods such as a subtractive method, an additive method, a semi-additive method, and a modified semi-additive (MSAP) method. Therefore, although not shown in the drawing, a seed layer, which is a lead wire of electroplating, may be provided between the substrate member 10 and the lower wiring layer 110a.

Next, as in FIG. 4, the step of applying a photoresist 20 on the surface of the substrate member 10 on which the lower wiring layer 110a is formed is performed.

The photoresist 20 may be a negative type of which a light receiving portion is cured by photopolymerization. Therefore, when light is irradiated after attaching an exposure mask 30 to the photoresist 20 in the position in which the via electrode 130 is to be formed as in FIG. 5, the portion of the photoresist 20 to which the exposure mask 30 is attached can't receive light and is formed into a via hole 130′ which exposes the lower wiring layer 110a as in FIG. 6 after a subsequent developing process.

Here, the area of the exposure mask 30 attached to the formation position of the via electrode 130 corresponds to the area of the upper surface 130b of the via electrode 130. Therefore, it is possible to form the trapezoid via hole 130′ as in FIG. 6 by irradiating light while appropriately adjusting the light absorption rate of the photoresist 20, the wavelength of a light source, the quantity of light, etc. to relatively reduce a photopolymerization rate.

Next, as in FIG. 7, the step of forming the via electrode 130 by filling the inside of the via hole 130′ through plating is performed. This step may be performed by filling one metal material of Cu, Ag, Sn, Au, Ni, and Pd in the inside of the via hole 130′ through various methods such as screen printing, sputtering, evaporation, inkjetting, and dispensing. However, in order to increase the filling density of the corner portion (A of FIG. 6) of the trapezoid via hole 130′, it is preferred to grow the via electrode 130 to the height of the via hole 130′ through plating by performing electroplating using the lower wiring layer 110a as a lead wire.

When the via electrode 130 is formed like this, the step of removing the photoresist 20 using an etching solution etc. as in FIG. 8 and forming an insulating layer 120 to bury the lower wiring layer 110a and the via electrode 130 as in FIG. 9 using various coating methods such as a tape casting method, a spin coating method, and an inkjet printing method is performed.

Here, as the via electrode 130 has a trapezoid shape, it is possible to perform high filling ratio coating even in the bonded portion B of the via electrode 130 and the lower wiring layer 110a when coating the insulating layer 120. If the via electrode 130 has an inverted trapezoid shape in which the diameter thereof decreases downward, it may be difficult to fill an insulating material since the bonded portion B of the via electrode 130 and the lower wiring layer 110a is depressed inward.

Meanwhile, it is preferred that the thickness of the coated insulating layer 120 corresponds to the sum of the thickness of the lower wiring layer 110a and the via electrode 130 so that an upper wiring layer 110b, which is to be formed on the insulating layer 120 later, can be bonded to the upper surface 130b of the via electrode 130. Otherwise, a polishing process may be performed to expose the upper surface 130b of the via electrode 130 after coating the insulating layer 120 to completely cover the upper surface 130b of the via electrode 130.

When the insulating layer 120 is formed like this, finally, as in FIG. 10, the upper wiring layer 110b, which is bonded to the upper surface 130b of the via electrode 130, is formed on the insulating layer 120 to finally complete the printed circuit board of the present invention.

Like the lower wiring layer 110a, the upper wiring layer 110b may be formed by one of the generally known circuit forming methods such as a subtractive method, an additive method, a semi-additive method, and a modified semi-additive (MSAP) method. And after the upper wiring layer 110b is formed, it is possible to stack the wiring layers connected by the via electrode 130 in the desired number of layers by repeatedly performing the processes of FIGS. 4 to 10 on the upper wiring layer 110b or perform the above processes on the both surfaces of the substrate member 10.

Like this, the present invention can prevent a void or dimple phenomenon due to a conventional via fill process by coating the insulating layer 120 after forming the via electrode 130 first, thus greatly improving reliability of electrical connection even in the stack via structure.

Further, it is possible to provide a structurally stable printed circuit board by effectively dispersing stress due to stacking load according to the trapezoid structure of the via electrode 130.

According to the printed circuit board and the method of fabricating the same, it is possible to prevent a void or dimple phenomenon due to a conventional via fill process, thus greatly improving reliability of electrical connection even in a stack via structure.

Further, it is possible to provide a structurally stable printed circuit board by effectively dispersing stress due to stacking load according to the trapezoid structure of a via electrode.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A printed circuit board comprising a lower wiring layer, an insulating layer which buries the lower wiring layer, and an upper wiring layer formed on the insulating layer, wherein the interlayer connection between the upper wiring layer and the lower wiring layer is performed by a via electrode which is provided between the upper wiring layer and the lower wiring layer and has an upper surface bonded to the upper wiring layer and a lower surface bonded to the lower wiring layer, wherein the lower surface of the via electrode is larger than the upper surface thereof.

2. The printed circuit board according to claim 1, wherein the via electrode has a tapered sidewall so that the diameter thereof increases downward.

3. The printed circuit board according to claim 1, wherein the insulating layer is formed to bury the lower wiring layer and the via electrode after the via electrode is formed.

4. The printed circuit board according to claim 1, wherein the wiring layer consists of one or a combination of a signal line, a power line, and a ground line.

5. A printed circuit board formed by repeatedly stacking a wiring layer and an insulating layer which buries the wiring layer on one or both surfaces of a substrate member, wherein the interlayer connection between the wiring layers is performed by a via electrode which is provided between the wiring layers and has a lower surface bonded to the wiring layer buried in the insulating layer and an upper surface bonded to the wiring layer formed on the insulating layer based on one insulating layer, wherein the lower surface of the via electrode is larger than the upper surface thereof.

6. The printed circuit board according to claim 5, wherein the via electrode has a tapered sidewall so that the diameter thereof increases downward.

7. The printed circuit board according to claim 5, wherein the via electrodes of the respective layers are disposed in the opposite positions in the vertical direction.

8. A method of fabricating a printed circuit board, comprising:
forming a lower wiring layer on a substrate member;
applying a photoresist on the surface of the substrate member on which the lower wiring layer is formed;
exposing the lower wiring layer by forming a tapered via hole, whose diameter increases downward, in the photoresist;
forming a via electrode by filling the inside of the via hole through plating;
removing the photoresist;
forming an insulating layer to bury the lower wiring layer and the via electrode; and
forming an upper wiring layer on the insulating layer to be bonded to an upper surface of the via electrode.

9. The method of fabricating a printed circuit board according to claim 8, wherein in forming the insulating layer, the insulating layer is formed to have a thickness corresponding to the sum of the thickness of the lower wiring layer and the thickness of the via electrode.

10. The method of fabricating a printed circuit board according to claim 8, wherein the lower wiring layer and the upper wiring layer are formed by one of a subtractive method, an additive method, a semi-additive method, and a modified semi-additive (MSAP) method.

11. The method of fabricating a printed circuit board according to claim 8, wherein the photoresist is a negative type that is cured by light irradiation, and in forming the via hole, the via hole is formed by performing exposure and development after attaching an exposure mask to the photoresist in the position in which the via electrode is to be formed.

12. The method of fabricating a printed circuit board according to claim 11, wherein the area of the exposure mask attached to the position in which the via electrode is to be formed corresponds to the area of the upper surface of the via electrode.

13. The method of fabricating a printed circuit board according to claim 8, wherein in forming the via electrode, the via electrode is formed by performing electroplating using the lower wiring layer as a lead wire.
